(19) United States
(12) Patent Application Publication
(10) Pub. No.: US 2015/0091163 A1
(43) Pub. Date: Apr. 2, 2015

(54) DRIVER INTEGRATED CIRCUIT CHIP, DISPLAY DEVICE HAVING THE SAME, AND METHOD OF MANUFACTURING A DRIVER INTEGRATED CIRCUIT CHIP

(71) Applicant: Samsung Display Co., LTD., Yongin-City (KR)

(72) Inventor: Dong-Wook KIM, Daejeon (KR)

(21) Appl. No.: 14/490,373

(22) Filed: Sep. 18, 2014

(30) Foreign Application Priority Data
Oct. 1, 2013 (KR) 10-2013-0117107

(51) Int. Cl. H01L 23/00; H01L 21/768

(52) U.S. Cl. CPC H01L 24/14; H01L 24/11; H01L 21/76802; H01L 2924/14; H01L 2924/13069; H01L 2224/14132; H01L 2224/14517; H01L 2224/1357; H01L 2224/13022; H01L 2224/1182; H01L 2224/11831; H01L 2224/113
USPC 257/737; 438/613

(57) ABSTRACT

A driver integrated circuit chip is provided. The driver integrated circuit chip includes a base substrate including at least one driver integrated circuit, a plurality of metal lines, and a passivation layer covering the driver integrated circuit and the metal lines; a plurality of input bumps arranged near a first longer side of the base substrate; a plurality of output bumps arranged near a second longer side of the base substrate; and a plurality of dummy bumps arranged on a central region of the base substrate, the dummy bumps being arranged between the input bumps and the output bumps. Each of the dummy bumps has a stacked layer structure that is different from a stacked layer structure of each of the input bumps and the output bumps.

### CROSS REFERENCE TO RELATED APPLICATION

This application claims priority under 35 USC §119 to Korean Patent Application No. 10-2013-0117107 filed on Oct. 1, 2013 in the Korean Intellectual Property Office (KIPO), the disclosure of which is incorporated by reference in its entirety herein.

### BACKGROUND

1. Technical Field

The inventive concept relates to a display device. More particularly, the inventive concept relates to a driver integrated circuit chip, a display device including the driver integrated circuit chip, and a method of manufacturing the driver integrated circuit chip.

2. Related Art

In general, a display device may include a display panel and a driver integrated circuit chip. The display panel may include a plurality of pixels, and the driver integrated circuit chip may be configured to drive the display panel. The driver integrated circuit chip may include a plurality of input bumps and a plurality of output bumps to electrically couple a plurality of internal circuits in the driver integrated circuit chip to the display panel. In addition, the driver integrated circuit chip may be mounted on the display panel using the input bumps and the output bumps.

The size of the driver integrated circuit chip has increased in recent years as more internal circuits are integrated into the driver integrated circuit chip. The increase in chip size may cause the driver integrated circuit chip to warp significantly when the chip is mounted on the display panel. The chip warpage is due to the CTE (Coefficient of Thermal Expansion) mismatch between the chip and display panel, and also the layout of the bumps (the input and output bumps are typically arranged near the edges of the driver integrated circuit chip, where maximum CTE mismatch occurs). As a result of the warpage, cracks may occur in the driver integrated circuit chip.

In addition, the chip warpage exerts stresses near the edges of the driver integrated circuit chip, and the stresses may cause the interconnects (input bumps and output bumps) between the driver integrated circuit chip and the display panel to crack or deform. As a result of defects in the interconnects, a contact resistance between the driver integrated circuit chip and the display panel may increase.

### SUMMARY

The present disclosure is directed to address at least the above problems relating to chip warpage.

According to some embodiments of the inventive concept, a driver integrated circuit chip is provided. The driver integrated circuit chip includes a base substrate including at least one driver integrated circuit, a plurality of metal lines, and a passivation layer covering the driver integrated circuit and the metal lines; a plurality of input bumps arranged near a first longer side of the base substrate; a plurality of output bumps arranged near a second longer side of the base substrate; and a plurality of dummy bumps arranged on a central region of the base substrate, the dummy bumps being arranged between the input bumps and the output bumps, wherein each of the dummy bumps has a stacked layer structure that is different from a stacked layer structure of each of the input bumps and the output bumps.

In some embodiments, a first metal may be stacked on portions of the passivation layer where the dummy bumps are arranged.

In some embodiments, the first metal may be stacked on portions of the metal lines where the input bumps and the output bumps are arranged.

In some embodiments, the passivation layer may include an insulating material.

In some embodiments, the base substrate may include a plurality of openings exposing portions of the metal lines, the openings being formed by partially etching the passivation layer.

In some embodiments, the input bumps and the output bumps may be formed on the openings.

In some embodiments, the dummy bumps may be formed on the passivation layer.

In some embodiments, the input bumps may be arranged in at least one row near the first longer side of the base substrate, and the output bumps may be arranged in at least one row near the second longer side of the base substrate.

According to some other embodiments of the inventive concept, a display device comprising a display panel and a plurality of driver integrated circuit chips for driving the display panel is provided. Each of the driver integrated circuit chips includes a base substrate including at least one driver integrated circuit, a plurality of metal lines, and a passivation layer covering the driver integrated circuit and the metal lines; a plurality of input bumps arranged near a first longer side of the base substrate; a plurality of output bumps arranged near a second longer side of the base substrate; and a plurality of dummy bumps arranged on a central region of the base substrate, the dummy bumps being arranged between the input bumps and the output bumps, wherein each of the dummy bumps has a stacked layer structure that is different from a stacked layer structure of each of the input bumps and the output bumps.

In some embodiments, the driver integrated circuit chips may include at least one of a scan driving unit, a data driving unit, and a timing control unit.

In some embodiments, the display panel may include a display area where a plurality of pixels are arranged and a mounting area where the driver integrated circuit chips are arranged, and the driver integrated circuit chips may be configured to transmit electrical signals to the pixels.

In some embodiments, a first metal may be stacked on portions of the passivation layer where the dummy bumps are arranged.

In some embodiments, the first metal may be stacked on portions of the metal lines where the input bumps and the output bumps are arranged.

In some embodiments, the passivation layer may include an insulating material.

In some embodiments, the base substrate may include a plurality of openings exposing portions of the metal lines, the openings being formed by partially etching the passivation layer.

In some embodiments, the input bumps and the output bumps may be formed on the openings.

In some embodiments, the dummy bumps may be formed on the passivation layer.

In some embodiments, the input bumps may be arranged in at least one row near the first longer side of the base substrate, and the output bumps may be arranged in at least one row near the second longer side of the base substrate.

According to some further embodiments of the inventive concept, a method of manufacturing a driver integrated circuit chip is provided. The method includes forming a base substrate, wherein the base substrate includes at least one driver integrated circuit, a plurality of metal lines, and a passivation layer covering the driver integrated circuit and the metal lines; forming a plurality of openings by partially etching the passivation layer, wherein the openings expose portions of the metal lines and are formed near a first longer side of the base substrate and a second longer side of the base substrate; and forming a plurality of input bumps and a plurality output bumps on the openings and a plurality of dummy bumps on the passivation layer.

In some embodiments, the dummy bumps may be arranged on a central region of the base substrate between the input bumps and the output bumps, and wherein the input bumps may be arranged in at least one row near the first longer side of the base substrate and the output bumps may be arranged in at least one row near the second longer side of the base substrate.

### BRIEF DESCRIPTION OF THE DRAWINGS

FIG. 1 is a plane view of a driver integrated circuit chip according to an embodiment of the inventive concept.

FIG. 2 is a side view of the bumps in the driver integrated circuit chip of FIG. 1.

FIG. 3A is a cross-sectional view of a stacked layer structure of a dummy bump in the driver integrated circuit chip of FIG. 1 according to an embodiment of the inventive concept.

FIG. 3B is a cross-sectional view of a stacked layer structure of a dummy bump in the driver integrated circuit chip of FIG. 1 according to another embodiment of the inventive concept.

FIG. 4 is a block diagram of a display device according to an embodiment of the inventive concept.

FIG. 5 illustrates a driver integrated circuit chip mounted on a display panel in the display device of FIG. 4.

FIG. 6 is a cross-sectional view of the driver integrated circuit chip mounted on the display panel in the display device of FIG. 4.

FIG. 7 is a flow chart illustrating a method of manufacturing a driver integrated circuit chip according to an embodiment of the inventive concept.

### DETAILED DESCRIPTION

The inventive concept is described more fully herein with reference to the accompanying drawings. The inventive concept may, however, be embodied in many different forms, and should not be construed as being limited to the described embodiments. In the drawings, the sizes and relative sizes of layers and regions may be exaggerated for clarity.

It will be understood that when an element or layer is referred to as being “on,” “connected to,” or “coupled to” another element or layer, it can be directly on, connected, or coupled to the other element or layer, or with one or more intervening elements or layers being present. In contrast, when an element is referred to as being “directly on,” “directly connected to,” or “directly coupled to” another element or layer, there are no intervening elements or layers present. Like or similar reference numerals refer to like or similar elements throughout. As used herein, the term “and/or” includes any and all combinations of one or more of the associated listed items.

It will be understood that, although the terms “first,” “second,” “third,” etc. may be used herein to describe various elements, components, regions, layers, patterns and/or sections, the disclosed elements, components, regions, layers, patterns and/or sections should not be limited by these terms. These terms are merely used to distinguish one element, component, region, layer, pattern, or section from another element, component, region, layer, pattern, or section. Thus, a first element, component, region, layer, pattern, or section discussed below could be termed a second element, component, region, layer, pattern, or section without departing from the teachings of the exemplary embodiments.

Spatially relative terms, such as “beneath,” “below,” “lower,” “above,” “upper,” and the like, may be used herein to describe an element or feature's spatial relationship to another element(s) or feature(s) as illustrated in the figures. It will be understood that the spatially relative terms are intended to encompass different orientations of the device while in use or during operation, in addition to the orientations depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein should be interpreted accordingly.

The terminology used herein is for the purpose of describing particular exemplary embodiments and is not intended to limit the inventive concept. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Exemplary embodiments are described herein with reference to cross-sectional illustrations that are schematic illustrations of idealized exemplary embodiments (and intermediate structures) of the inventive concept. As such, variations from the shapes of the illustrations as a result of, for example, manufacturing techniques and/or tolerances, are to be expected. Thus, the exemplary embodiments should not be construed as being limited to the particular shapes of regions illustrated herein, but may also include deviations in shapes that result, for example, from manufacturing tolerances. The regions illustrated in the figures are schematic in nature, and their shapes are not intended to illustrate the actual shape of a region of a device, and should not be construed to limit the scope of the inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and should not be interpreted in an idealized or overly formal sense unless expressly defined herein.

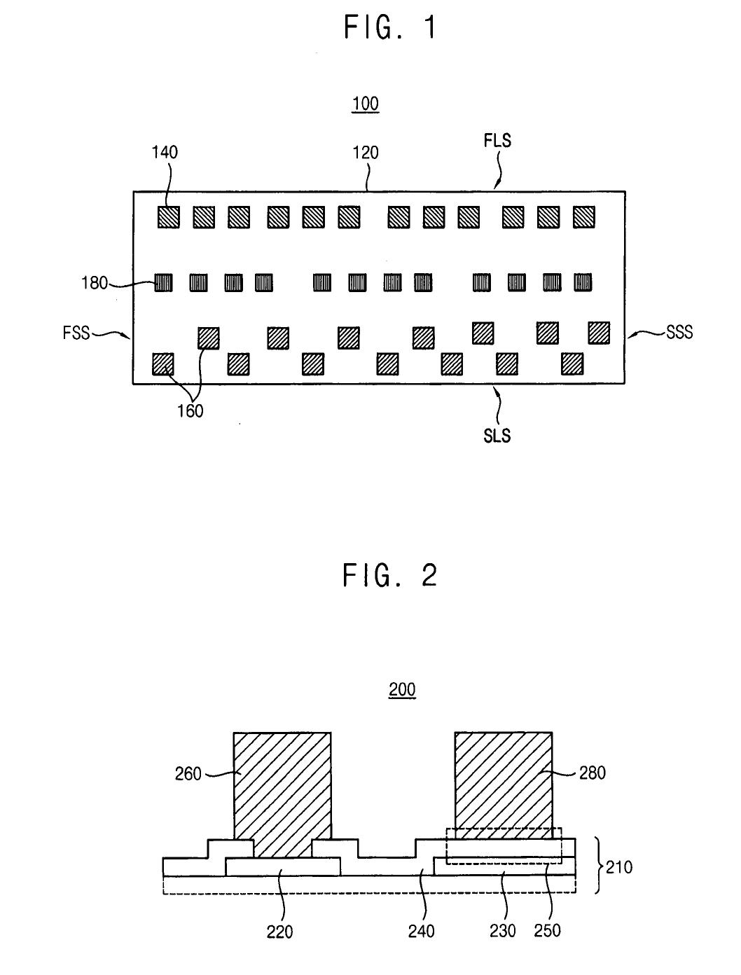

FIG. 1 is a plane view of a driver integrated circuit chip according to an embodiment of the inventive concept.

Referring to FIG. 1, a driver integrated circuit chip 100 may include a base substrate 120, a plurality of input bumps 140, a plurality of output bumps 160, and a plurality of dummy bumps 180.

The base substrate 120 may include at least one driver integrated circuit (D-IC), a plurality of metal lines, and a passivation layer covering the driver integrated circuit (D-IC) and the metal lines. The base substrate 120 may be formed having a square shape including two longer sides FLS (first longer side) and SLS (second longer side), and two shorter sides FSS (first shorter side) and SSS (second shorter side).

The driver integrated circuit (D-IC) may be formed on the base substrate 120. The driver integrated circuit (D-IC) may generate a driving signal to drive a plurality of pixels in a display device. The driver integrated circuit (D-IC) may include a data driver integrated circuit, a scan driver integrated circuit, and/or a timing control driver integrated circuit. Accordingly, the driver integrated circuit chip 100 may include at least one of a scan driver unit, a data driver unit, and a timing control unit. The driver integrated circuit (D-IC) may include at least one thin film transistor (TFT). The driver integrated circuit (D-IC) may be formed by a semiconductor manufacturing process.

The metal lines may electrically couple the driver integrated circuit (D-IC) to the input bumps 140 and the output bumps 160.

The passivation layer may be formed covering the base substrate 120. Therefore, the passivation layer may protect the base substrate 120, the driver integrated circuit (D-IC), and the metal lines from physical and/or electrical damage. In some embodiments, the passivation layer may include an insulating material. For example, the insulating material may include silica, silicon nitride, electrical insulating resin, etc. However, the insulating material included in the passivation layer is not limited thereto, and may include other types of insulating materials.

In some embodiments, the input bumps 140 may be arranged near the first longer side FLS of the base substrate 120. As illustrated in FIG. 1, the input bumps 140 may be arranged in one row. However, the arrangement of the input bumps 140 is not limited to the configuration shown in FIG. 1. For example, in some other embodiments, the input bumps 140 may be arranged in more than one row.

The input bumps 140 may transmit electrical signals (e.g., a power voltage, a data signal, a clock signal, a picture signal, etc.) from an external device to the internal driver integrated circuit (D-IC) of the base substrate 120. However, the electrical signals are not limited thereto, and may include other types of electrical signals.

The output bumps 160 may be arranged near the second longer side SLS of the base substrate 120. In some embodiments, for example as illustrated in FIG. 1, the output bumps 160 may be arranged in two rows. However, the arrangement of the output bumps 160 is not limited to the configuration shown in FIG. 1. For example, in some other embodiments, the output bumps 160 may be arranged in one row or more than two rows.

The output bumps 160 may transmit electrical signals (e.g., a timing signal, a scan signal, a data signal, etc.) from the internal driver integrated circuit (D-IC) of the base substrate 120 to an external device (e.g., to the display panel).

Accordingly, the input bumps 140 and the output bumps 160 may act as conductive bumps electrically connecting the driver integrated circuit chip 100 to an external device. In some embodiments, portions of the passivation layer may be removed (in the regions where the input bumps 140 and the output bumps 160 are to be arranged), thereby exposing the underlying metal lines. In those embodiments, a first metal may be stacked on the exposed portions of the metal lines prior to forming the input bumps 140 and the output bumps 160.

The dummy bumps 180 may be arranged in a row on a central region of the base substrate 120. As shown in FIG. 1, the central region of the base substrate 120 is located between the input bumps 140 and the output bumps 160. In some embodiments, a height of the dummy bumps 180 may be greater than or equal to a height of each of the input bumps 140 and the output bumps 160. The dummy bumps 180 may be formed on the passivation layer, such that the dummy bumps 180 do not contact with the driver integrated circuit (D-IC) and the metal lines. Thus, electrical signals may not be transmitted through the dummy bumps 180. By arranging the dummy bumps 180 in a row on the central region of the base substrate 120, the bonding force between the driver integrated circuit chip 100 and the display panel (or a substrate) may be increased. As a result, the dummy bumps 180 may prevent the central region of the driver integrated circuit chip 100 from warping due to tension (or stress).

In some embodiments, the input bumps 140, the output bumps 160, and the dummy bumps 180 may be formed of a same material. The input bumps 140 and the output bumps 160 may include a conductive material. The dummy bumps 180 may be formed using the same material as the input bumps 140 and the output bumps 160, so as to simplify the process of forming the bumps.

The metal lines coupled to the driver integrated circuit (D-IC) may contact with the input bumps 140 and the output bumps 160. Accordingly, the input bumps 140 and the output bumps 160 may transmit electrical signals to the metal lines. In some embodiments, the base substrate 120 may include a plurality of openings exposing portions of the metal lines, wherein the openings are formed by partially etching the passivation layer. For example, the openings may be formed (in the regions where the input bumps 140 and the output bumps 160 are to be arranged) using a mask etching process. The central region of the base substrate 120 (where the dummy bumps 180 are to be arranged) may be covered with a mask, so that the passivation layer in the central region is not removed by the etching process. It is noted that the forming of the openings is not limited to the above-described process, and may include other types of etching processes.

In some embodiments, the input bumps 140 and the output bumps 160 may be formed on the openings in the passivation layer. Thus, the input bumps 140 and the output bumps 160 may be formed in contact with the portions of the metal lines exposed by the etching process. The dummy bumps 180 may be formed on the passivation layer, such that the dummy bumps 180 do not receive any electrical signals. In some embodiments, a height of the dummy bumps 180 may range from about 600 nm to about 700 nm. In some embodiments, a height of the dummy bumps 180 may be greater than a height of conventional dummy dumps because the dummy bumps 180 are formed on the passivation layer (whereas the conventional dummy bumps are not formed on the passivation layer). Also, the height of the dummy bumps 180 may be greater than or equal to a height of each of the input bumps 140 and the output bumps 160.

In some embodiments, the input bumps 140 may be arranged in at least one row near the first longer side FLS of the base substrate 120, and the output bumps 160 may be arranged in at least one row near the second longer side SLS of the base substrate 120. Accordingly, signals may be easily transmitted between the driver integrated circuit chip 100 and an external device.

As described above, the dummy bumps 180 may have a stacked layer structure that is different from the stacked layer structures of the input bumps 140 and the output bumps 160. Further, a height of the dummy bumps 180 may be greater than or equal to a height of each of the input bumps 140 and the output bumps 160. Also, the dummy bumps 180 may be arranged on the central region of the base substrate 120, so that cracking and/or bending of the driver integrated circuit chip 100 may be prevented.

FIG. 2 is a side view of the bumps in the driver integrated circuit chip of FIG. 1.

Referring to FIG. 2, a driver integrated circuit chip 200 may include a base substrate 210 and a plurality of bumps 260 and 280. The base substrate 210 may include a driver integrated circuit (D-IC), a plurality of metal lines 220 and 230 for transmitting electrical signals, and a passivation layer 240.

A plurality of input bumps 260 may be formed on the metal lines 220 to transmit electrical signals from an external device to the driver integrated circuit (D-IC). Similarly, a plurality of output bumps (not illustrated) may be formed on the metal lines 230 to transmit electrical signals from the driver integrated circuit (D-IC) to the external device. A plurality of dummy bumps 280 may be formed on portions of the passivation layer 240 (the portions being denoted by a dotted region 250). As previously mentioned, the dummy bumps 280 do not transmit electrical signals.

The driver integrated circuit (D-IC) and the metal lines 220 and 230 may be formed on the base substrate 210 of the driver integrated circuit chip 200 through a semiconductor manufacturing process. After forming the driver integrated circuit (D-IC) and the metal lines 220 and 230, the passivation layer 240 may be formed (e.g. deposited) on the integrated circuit and the metal lines 220 and 230, so as to protect the integrated circuit and the metal lines 220 and 230 from electrical, physical, and/or chemical damage.

Several regions of the passivation layer 240 may be removed by an etching process using a mask, so as to expose the metal lines 220. In some embodiments, the base substrate 210 may include a plurality of openings exposing portions of the metal lines 220. The openings may be formed by partially etching the passivation layer 240. For example, the openings may be formed (in regions where the input bumps 260 and the output bumps are to be arranged) using a mask etching process. A central region of the base substrate 210 (where the dummy bumps 280 are to be arranged) may be covered with a mask, so that the passivation layer 250 in the central region is not removed by the etching process. It is noted that the forming of the openings is not limited to the above-described process, and may include other types of etching processes.

The input bumps 260, the output bumps (not illustrated), and the dummy bumps 280 may be simultaneously formed after the etching process. In some embodiments, the input bumps 260 and the output bumps may be formed on the openings in the passivation layer. Thus, the input bumps 260 and the output bumps may directly contact with the metal lines 220, and electrical signals may be transmitted through the input bumps 260 and the output bumps. The dummy bumps 280 may be formed on the passivation layer 250 located in a central region of the base substrate 210. Therefore, a height of the dummy bumps 280 may be greater than a height of conventional dummy bumps. Also, the height of the dummy bumps 280 may be greater than or equal to a height of each of the input bumps 260 and the output bumps. The input bumps 260, the output bumps, and the dummy bumps 280 may be formed of a same material. The input bumps 260 and the output bumps may include conductive materials. Accordingly, the input bumps 260 and the output bumps may act as conductive bumps. The dummy bumps 280 may be formed using the same material as the input bumps 260 and the output bumps, so as to simplify the process of forming the bumps.

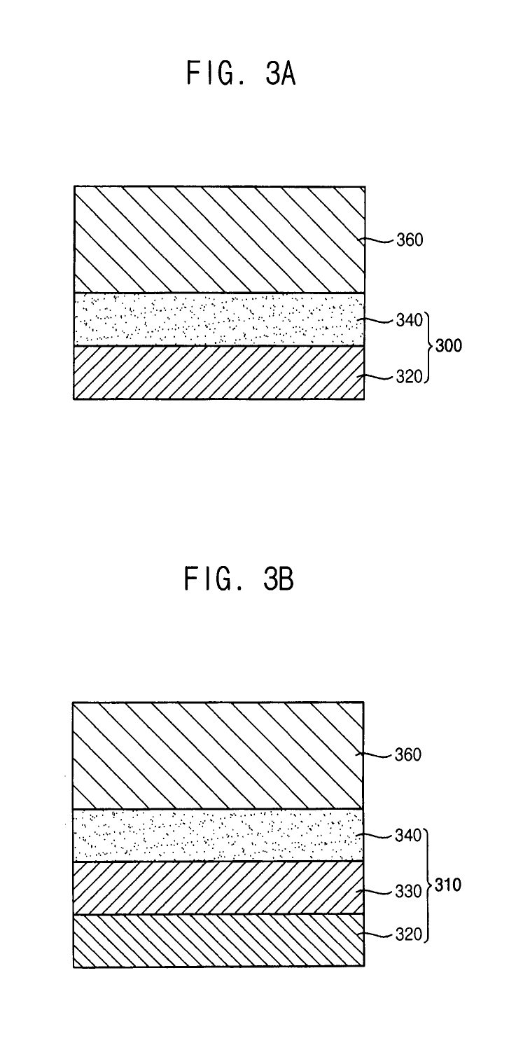

FIG. 3A is a cross-sectional view of a stacked layer structure of a dummy bump in the driver integrated circuit chip of FIG. 1 according to an embodiment of the inventive concept.

Referring to FIG. 3A, a dummy bump 360 may be formed on a base substrate 300. The base substrate 300 may include a driver integrated circuit 320 and a passivation layer 340.

The driver integrated circuit 320 may include thin film transistors formed by a semiconductor manufacturing process. In a display device, the driver integrated circuit 320 may generate driving signals to drive a plurality of pixels in a display panel. The driver integrated circuit 320 may include a data driving integrated circuit, scan driving integrated circuit, and/or a timing controlling integrated circuit. However, the driver integrated circuit 320 is not limited thereto, and may include other types of integrated circuits.

The dummy bump 360 may be formed on the passivation layer 340. Thus, a height of a stacked layer structure of the dummy bump 360 may be greater than a height of a stacked layer structure of a conventional dummy bump. Further, the stacked layer structure of the dummy bumps 360 may be formed having a same height as a stacked layer structure of each of the input bumps and/or the output bumps. In some embodiments, the height of the stacked layer structure of the dummy bumps 360 may be greater than the height of each of the stacked layer structures of the input bumps and/or the output bumps. Since the above stacked layer structures have been previously described, a detailed description of those structures shall therefore be omitted.

FIG. 3B is a cross-sectional view of a stacked layer structure of a dummy bump in the driver integrated circuit chip of FIG. 1 according to another embodiment of the inventive concept.

Referring to FIG. 3B, a dummy bump 360 may be formed on a base substrate 310. The base substrate 310 may include a driver integrated circuit 320, a plurality of metal lines 330, and a passivation layer 340. The driver integrated circuit 320 may include thin film transistors having a plurality of metal layers. For example, when a thin film transistor comprises a double gate structure, a first region (where the driver integrated circuit 320 is arranged on the base substrate 310) may be formed higher than other regions. Further, the metal lines 330 may be formed on the driver integrated circuit 320. Thus, a height of the stacked layer structure of the dummy bump 360 in FIG. 3B may be greater than a height of the stacked layer structure of the dummy bump 360 in FIG. 3A.

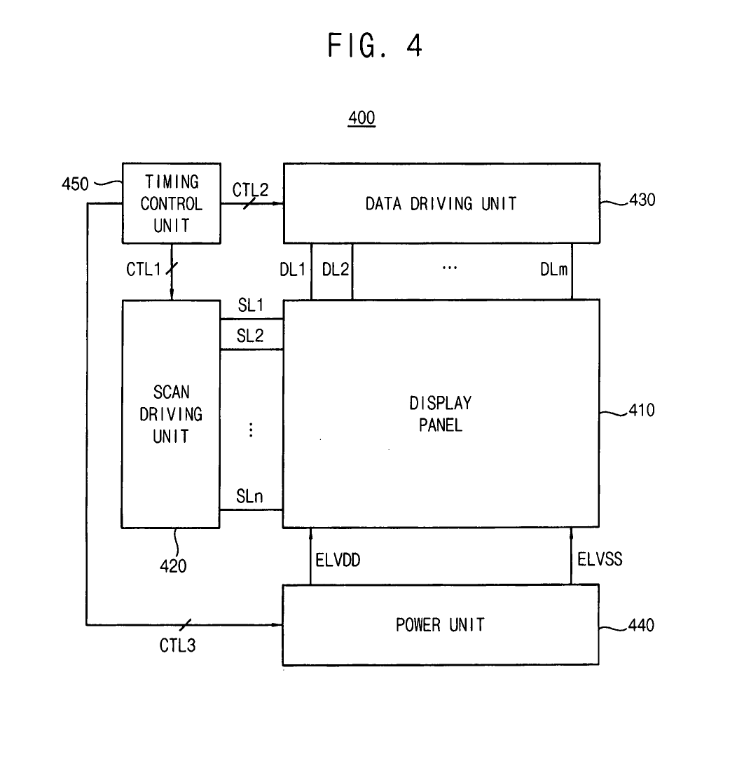

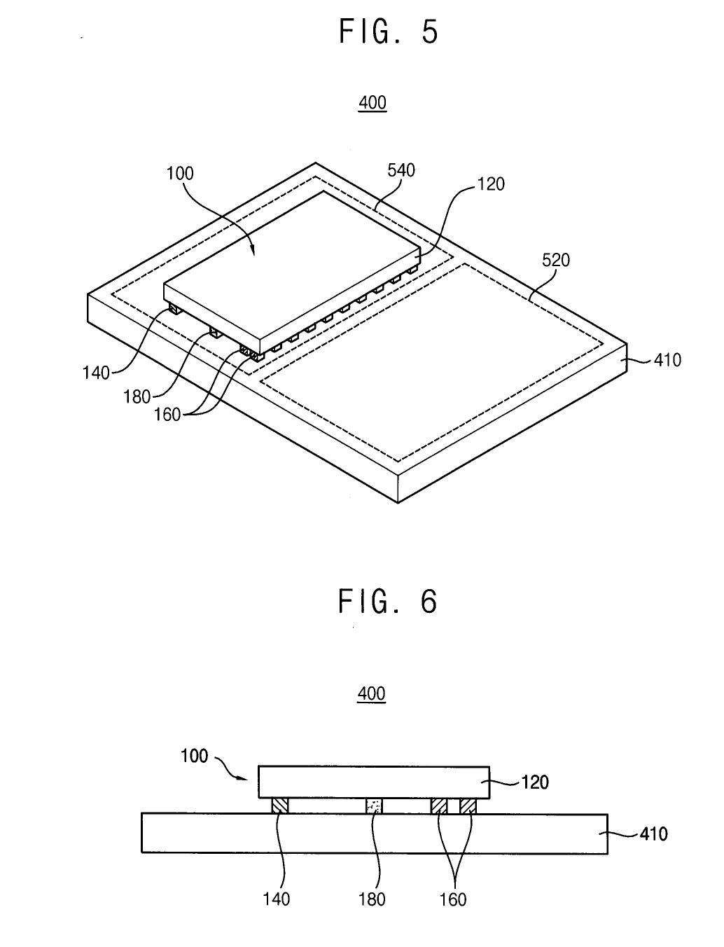

FIG. 4 is a block diagram of a display device according to an embodiment of the inventive concept. FIG. 5 illustrates a driver integrated circuit chip mounted on a display panel in the display device of FIG. 4. FIG. 6 is a cross-sectional view of the driver integrated circuit chip mounted on the display panel in the display device of FIG. 4.

Referring to FIG. 4 through FIG. 6, a display device 400 may include a display panel 410, a scan driving unit 420, a data driving unit 430, a power unit 440, and a timing control unit 450. The display device 400 may include the driver integrated circuit chip 100 of FIG. 1. In some embodiments, the driver integrated circuit chip 100 may include at least one of the scan driving unit 420, the data driving unit 430, and the timing control unit 450.

The driver integrated circuit chip 100 may also include a base substrate 120 having at least one driver integrated circuit (D-IC), a plurality of metal lines, a passivation layer covering the driver integrated circuit (D-IC) and the metal lines, a plurality of input bumps 140 arranged near a first longer side FLS of the base substrate 120, a plurality of output bumps 160 arranged near a second longer side SLS of the base substrate 120, and a plurality of dummy bumps 180 arranged on a central region of the base substrate 120, wherein the central region of the base substrate 120 is located between the input bumps 140 and the output bumps 160. Thus, the dummy bumps 180 may be arranged in an island shape.

The display panel 410 may include a plurality of pixels (i.e., a plurality of pixel circuits). The scan driving unit 420 may provide a scan signal to the pixel circuits through a plurality of scan lines SL1 through SLn. The data driving unit 430 may provide a data signal to the pixel circuits through a plurality of data lines DL1 through DLm. The power unit 440 may generate a high-power voltage ELVDD and a low-power voltage ELVSS, and may provide the high-power voltage ELVDD and the low-power voltage ELVSS to the pixel circuits through a plurality of power lines. The timing control unit 450 may control the scan driving unit 420, the data driving unit 430, and the power unit 440. The timing control unit 450 may generate a plurality of control signals CTL1, CTL2, and CTL3, and may provide the control signals CTL1, CTL2, and CTL3 to the scan driving unit 420, the data driving unit 430, and the power unit 440, respectively. Although FIG. 4 illustrates the scan driving unit 420, data driving unit 430, power unit 440, and timing control unit 450 as being separately implemented, it should be noted that the scan driving unit 420, data driving unit 430, power unit 440, and timing control unit 450 may be combined. In some embodiments, the functions of the scan driving unit 420, data driving unit 430, power unit 440, and timing control unit 450 may be performed by at least one peripheral circuit coupled to the display panel 410. For example, a timing control unit may perform operations of a scan driving unit, a data driving unit, and a power unit, or may include at least one component for performing operations of a scan driving unit, a data driving unit, and a power unit.

As illustrated in FIG. 5 and FIG. 6, the driver integrated circuit chip 100 may be mounted on the display panel 410 via the plurality of bumps 140, 160, and 180.

In some embodiments, the display panel 410 may include a display area 520 (where a plurality of pixels are arranged) and a mounting area 540 (where the driver integrated circuit chip 100 is arranged), with the driver integrated circuit chip 100 transmitting electrical signals to the pixels. The driver integrated circuit chip 100 may be mounted on the mounting area 540 to enable high resolution of the display device 400. The driver integrated circuit chip 100 may be mounted on the mounting area 540 using techniques such as chip on glass (COG), tape carrier package (TCP) using tape automated bonding (TAB), chip on flexible printed circuit (COF), chip on board (COB), etc.

The driver integrated circuit chip 100 may output signals for displaying texts and/or images. The driver integrated circuit (D-IC) may include a data driving integrated circuit (or a source driving integrated circuit), a scan driving integrated circuit (or a gate driving integrated circuit), and/or a timing controlling integrated circuit. In some embodiments, the data driving integrated circuit, the scan driving integrated circuit, and/or the timing controlling integrated circuit may be integrated into a single driver integrated circuit chip 100. For example, the driver integrated circuit chip 100 may include a one-chip solution integrating the data driving integrated circuit and the scan driving integrated circuit.

The driver integrated circuit chip 100 may include the plurality of bumps 140, 160, and 180 for coupling the display panel 410 to the driver integrated circuits (D-ICs) of the base substrate 120. Further, the driver integrated circuit chip 100 may be mounted onto the display panel 410 via the plurality of bumps 140, 160, and 180. In some embodiments, for example as illustrated in FIG. 5, the input bumps 140 may be arranged in at least one row near the first longer side FLS of the base substrate 120, and the output bumps 160 may be arranged in at least one row near the second longer side SLS of the base substrate 120.

The input bumps 140 may transmit electrical signals (e.g., a power voltage, a data signal, a clock signal, a picture signal, etc.) from an external device (e.g., the display panel 410 or a flexible printed circuit board) to the internal driver integrated circuit (D-IC) of the base substrate 120. Further, the output bumps 160 may transmit electrical signals (e.g., a timing signal, a scan signal, a data, a picture signal, etc.) from the internal driver integrated circuit (D-IC) of the base substrate 120 to the external device (e.g., to the display panel 410). In other words, the input bumps 140 and the output bumps 160 may act as conductive bumps electrically connecting the driver integrated circuit chip 100 to an external device. In some embodiments, a first metal may be stacked on the exposed portions of the metal lines (exposed due to the removal of the passivation layer) prior to forming the input bumps 140 and the output bumps 160 on those exposed portions.

The passivation layer may be formed covering the base substrate 120. Therefore, the passivation layer may protect the base substrate 120, the driver integrated circuit (D-IC), and the metal lines from physical and/or electrical damage. In some embodiments, the passivation layer may include an insulating material.

Referring to FIG. 6, a height of the dummy bumps 180 may be greater than or equal to a height of each of the input bumps 140 and the output bumps 160. The dummy bumps 180 may be arranged on a central region of the base substrate 120. The dummy bumps 180 are formed on the passivation layer, such that the dummy bumps 180 do not contact with the driver integrated circuit (D-IC) and/or the metal lines. The dummy bumps 180 may be arranged in a row on the central region of the base substrate 120, so that the bonding force between the driver integrated circuit chip 100 and the display panel (or, a substrate) may be increased. The dummy bumps 180 may prevent the central region of the driver integrated circuit chip 100 from warping due to tension (or stress). The dummy bumps 180 may be formed using a same material as the input bumps 140 and the output bumps 160, so as to simplify the process of forming the bumps.

In some embodiments, the base substrate 120 may include a plurality of openings exposing portions of the metal lines, wherein the openings are formed by partially etching the passivation layer. However, the forming of the openings is not limited to the above-described process, and may include other types of etching processes. In some embodiments, the input bumps 140 and the output bumps 160 may be formed on the openings in the passivation layer.

The passivation layer in the central region of the base substrate 120 (where the dummy bumps 180 are to be arranged) is not removed, and therefore the dummy bumps 180 may be formed on the passivation layer. Accordingly, a height of the dummy bumps 180 may be greater than a height of a conventional dummy bump. Since the above embodiments have been previously described with reference to FIG. 1 through FIG. 3B, a detailed description of those embodiments shall therefore be omitted.

As described above, the dummy bumps 180 are arranged in a row in a central region of the driver integrated circuit chip 100, and each of the dummy bumps 180 has a stacked layer structure that is different from the stacked layer structures of the input bumps 140 and the output bumps 160. Accordingly, the arrangement and the stacked layer structure of the dummy bumps 180 may help prevent cracking and/or bending of the driver integrated circuit chip 100, thereby improving the durability of the display device 400. In addition, the contact resistance between the driver integrated circuit chip 100 and the display panel 410 may be lowered using the exemplary embodiments of the inventive concept, thereby reducing defects in data and/or signal transmission.

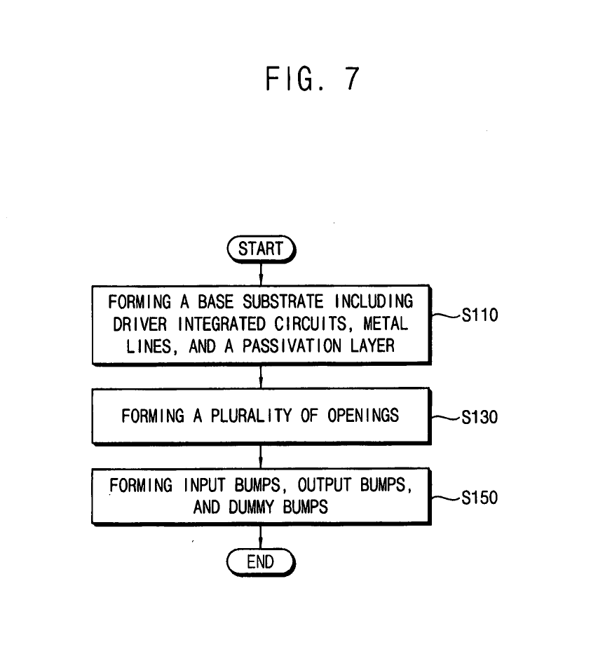

FIG. 7 is a flow chart illustrating a method of manufacturing a driver integrated circuit chip according to an embodiment of the inventive concept.

Referring to FIG. 7, the method may include forming a base substrate including at least one driver integrated circuit (D-IC), a plurality of metal lines, and a passivation layer covering the driver integrated circuit (D-IC) and the metal lines (S110), and forming a plurality of openings by partially etching the passivation layer (S130). The openings expose portions of the metal lines, and may be formed near a first longer side FLS of the base substrate and a second longer side SLS of the base substrate. The method may further include forming a plurality of input bumps, a plurality of output bumps, and a plurality of dummy bumps (S150). The input bumps and the output bumps may be formed on the openings in the passivation layer, and the dummy bumps may be formed on the passivation layer.

As previously described, the base substrate may include at least one driver integrated circuit (D-IC), the plurality of metal lines, and the passivation layer covering the driver integrated circuit (D-IC) and the metal lines. In a display device, the driver integrated circuit (D-IC) may generate driving signals for driving the pixels in a display panel. The driver integrated circuit (D-IC) may include a data driving integrated circuit, a scan driving integrated circuit, and/or a timing controlling integrated circuit. The metal lines may electrically couple the driver integrated circuit (D-IC) to the input bumps and the output bumps. The driver integrated circuit (D-IC) and the metal lines may be formed by a semiconductor manufacturing process. The passivation layer may be formed covering the driver integrated circuit (D-IC) and the metal lines. Thus, the passivation layer may protect the surface of the base substrate, the driver integrated circuit (D-IC), and the metal lines from physical and/or electrical damage. In some embodiments, the passivation layer may include an insulating material.

The plurality of openings may be formed by partially etching the passivation layer. The openings expose portions of the metal lines, and may be formed near a first longer side FLS of the base substrate and a second longer side SLS of the base substrate. For example, the openings may be formed (in regions where the input bumps 140 and the output bumps 160 are to be arranged) using a mask etching process. A central region of the base substrate 120 (where the dummy bumps 180 are to be arranged) may be covered with a mask, so that the passivation layer in the central region is not removed by the etching process. Since the above embodiments have been previously described, a detailed description of those embodiments shall therefore be omitted.

In some embodiments, the plurality of input bumps and the plurality of output bumps may be formed on the openings in the passivation layer, and the plurality of dummy bumps having island shapes may be simultaneously formed on the passivation layer. The input bumps and the output bumps may contact with the portions of the metal lines exposed by the etching process. The input bumps and the output bumps may transmit electrical signals. In some embodiments, the dummy bumps may be arranged in a row on the central region of the base substrate, wherein the central region is located between the input bumps and the output bumps. In some embodiments, the input bumps may be arranged in at least one row near the first longer side FLS of the base substrate, and the output bumps may be arranged in at least one row near the second longer side SLS of the base substrate. Each of the dummy bumps may have a stacked layer structure that is different from the stacked layer structures of the input bumps and the output bumps, so that a height of the dummy bumps may be greater than or equal to a height of each of the input bumps and the output bumps. Since the above embodiments have been previously described, a detailed description of those embodiments shall therefore be omitted.

As described above, the method of manufacturing the driver integrated circuit chip may be used to form dummy bumps having a stacked layer structure that is different from the stacked layer structures of the input bumps and the output bumps, without introducing additional manufacturing process steps. Thus, the method according to the inventive concept may have improved reproducibility compared to conventional manufacturing processes, and may also reduce production costs. Further, the dummy bumps may be arranged on the central region of the base substrate, so that cracking and/or bending of the driver integrated circuit chip may be prevented.

The aforementioned embodiments of the inventive concept may be applied to any electronic device including a display device. For example, the embodiments may be applied to a television, a mobile phone, a smart phone, a laptop computer, a tablet computer, a smart pad, a personal digital assistants (PDA), a portable multimedia player (PMP), a digital camera, a music player, a portable game console, a navigation device, etc.

The foregoing is merely illustrative of exemplary embodiments, and should not be construed as limiting the inventive concept. Those skilled in the art will readily appreciate that different modifications may be made to the embodiments without departing from the teachings of the inventive concept. Accordingly, all such modifications are intended to be included within the scope of the inventive concept.

What is claimed is:

1. A driver integrated circuit chip comprising:
a base substrate including at least one driver integrated circuit, a plurality of metal lines, and a passivation layer covering the driver integrated circuit and the metal lines;
a plurality of input bumps arranged near a first longer side of the base substrate;
a plurality of output bumps arranged near a second longer side of the base substrate; and
a plurality of dummy bumps arranged on a central region of the base substrate, the dummy bumps being arranged between the input bumps and the output bumps,
wherein each of the dummy bumps has a stacked layer structure that is different from a stacked layer structure of each of the input bumps and the output bumps.

2. The driver integrated circuit chip of claim 1, wherein a first metal is stacked on portions of the passivation layer where the dummy bumps are arranged.

3. The driver integrated circuit chip of claim 2, wherein the first metal is stacked on portions of the metal lines where the input bumps and the output bumps are arranged.

4. The driver integrated circuit chip of claim 3, wherein the passivation layer includes an insulating material.

5. The driver integrated circuit chip of claim 1, wherein the base substrate includes a plurality of openings exposing portions of the metal lines, the openings being formed by partially etching the passivation layer.

6. The driver integrated circuit chip of claim 5, wherein the input bumps and the output bumps are formed on the openings.

7. The driver integrated circuit chip of claim 6, wherein the dummy bumps are formed on the passivation layer.

8. The driver integrated circuit chip of claim 5, wherein the input bumps are arranged in at least one row near the first longer side of the base substrate, and the output bumps are arranged in at least one row near the second longer side of the base substrate.

9. A display device comprising a display panel and a plurality of driver integrated circuit chips for driving the display panel, wherein each of the driver integrated circuit chips includes:
a base substrate including at least one driver integrated circuit, a plurality of metal lines, and a passivation layer covering the driver integrated circuit and the metal lines;
a plurality of input bumps arranged near a first longer side of the base substrate;
a plurality of output bumps arranged near a second longer side of the base substrate; and
a plurality of dummy bumps arranged on a central region of the base substrate, the dummy bumps being arranged between the input bumps and the output bumps,
wherein each of the dummy bumps has a stacked layer structure that is different from a stacked layer structure of each of the input bumps and the output bumps.

10. The display device of claim 9, wherein the driver integrated circuit chips include at least one of a scan driving unit, a data driving unit, and a timing control unit.

11. The display device of claim 10, wherein the display panel includes a display area where a plurality of pixels are arranged and a mounting area where the driver integrated circuit chips are arranged, and the driver integrated circuit chips are configured to transmit electrical signals to the pixels.

12. The display device of claim 9, wherein a first metal is stacked on portions of the passivation layer where the dummy bumps are arranged.

13. The display device of claim 12, wherein the first metal is stacked on portions of the metal lines where the input bumps and the output bumps are arranged.

14. The display device of claim 13, wherein the passivation layer includes an insulating material.

15. The display device of claim 9, wherein the base substrate includes a plurality of openings exposing portions of the metal lines, the openings being formed by partially etching the passivation layer.

16. The display device of claim 15, wherein the input bumps and the output bumps are formed on the openings.

17. The display device of claim 16, wherein the dummy bumps are formed on the passivation layer.

18. The display device of claim 15, wherein the input bumps are arranged in at least one row near the first longer side of the base substrate, and the output bumps are arranged in at least one row near the second longer side of the base substrate.

19. A method of manufacturing a driver integrated circuit chip, comprising:
forming a base substrate, wherein the base substrate includes at least one driver integrated circuit, a plurality of metal lines, and a passivation layer covering the driver integrated circuit and the metal lines;
forming a plurality of openings by partially etching the passivation layer, wherein the openings expose portions of the metal lines and are formed near a first longer side of the base substrate and a second longer side of the base substrate; and
forming a plurality of input bumps and a plurality output bumps on the openings and a plurality of dummy bumps on the passivation layer.

20. The method of claim 19, wherein the dummy bumps are arranged on a central region of the base substrate between the input bumps and the output bumps, and wherein the input bumps are arranged in at least one row near the first longer side of the base substrate and the output bumps are arranged in at least one row near the second longer side of the base substrate.
